(19) United States
(12) Patent Application Publication
(10) Pub. No.: US 2022/0336873 A1
(43) Pub. Date: Oct. 20, 2022

(54) METHOD FOR CONTROLLING LOWER LIMIT OF STATE OF CHARGE OF POWER BATTERY, AND VEHICLE

(71) Applicant: GREAT WALL MOTOR COMPANY LIMITED, Baoding (CN)

(72) Inventors: Qing ZHAO, Baoding (CN); Shujiang CHEN, Baoding (CN)

(21) Appl. No.: 17/854,358

(22) Filed: Jun. 30, 2022

Related U.S. Application Data
(63) Continuation of application No. PCT/CN2021/077832, filed on Feb. 25, 2021.

(30) Foreign Application Priority Data
Feb. 25, 2020 (CN) 202010115664.8

(51) Int. Cl. H01M 10/44; H02J 7/00; G01R 31/382; B60L 58/13

(52) U.S. Cl. CPC H01M 10/443; H02J 7/0063; H02J 7/0048; G01R 31/382; B60L 58/13; H01M 2220/20

(57) ABSTRACT

A method for controlling a lower limit of a state of charge of a power battery and a vehicle is provided. The method provided by the present disclosure includes: detecting a minimum ambient temperature for at least a period of time; predicting a minimum ambient temperature within a preset period of time after the at least a period of time according to the minimum ambient temperature within the at least a period of time; determining, according to the minimum ambient temperature within the preset period of time, a minimum state of charge value that able to meet power requirements for starting an engine of a vehicle under the minimum ambient temperature within the preset period of time; and adjusting a lower limit of the state of charge according to the minimum state of charge value.

### CROSS REFERENCE TO RELATED APPLICATIONS

This application is a continuation application of PCT/CN2021/077832, having a filing date of Feb. 25, 2021, which claims priority to Chinese Patent Application No. 202010115664.8, having a filing date of Feb. 25, 2020, the entire contents all of which are incorporated herein by reference.

### FIELD OF TECHNOLOGY

The following relates to the technical field of new energy vehicles, and more particularly to a method and a device for controlling a lower limit of a state of charge of a power battery, and a vehicle.

### BACKGROUND

With the increasing emergence of energy crisis and environmental pollution, hybrid vehicles have become an important direction for the development of the automotive industry due to their outstanding advantages in energy saving and environmental protection. At present, the lower limit of the state of charge (SOC) of the power battery used in hybrid vehicles is constant during the use of the vehicle. When the battery of the vehicle is at a low SOC value and is powered off, the low SOC value of the battery may be insufficient to enable the vehicle to start normally at low temperature due to the decrease in ambient temperature, thus affecting the normal function of the vehicle when powering on next time.

### SUMMARY

An aspect relates to a method and a device for controlling a lower limit of a state of charge of a power battery, and a vehicle, to ensure that the SOC value of the battery can enable the vehicle to start normally in a low ambient environment.

To achieve the above aspect, the technical solution of the present disclosure is achieved as follows:

A method for controlling a lower limit of a state of charge of a power battery, and the method includes:

detecting, through a temperature sensor, a minimum ambient temperature for at least a period of time;

predicting a minimum ambient temperature within a preset period of time after the at least a period of time according to the minimum ambient temperature within the at least a period of time;

determining, according to the minimum ambient temperature within the preset period of time, a minimum state of charge value that able to meet power requirements for starting an engine of a vehicle under the minimum ambient temperature within the preset period of time; and

adjusting a lower limit of the state of charge according to the minimum state of charge value.

In one embodiment, the minimum ambient temperature within the at least a period of time only includes a minimum ambient temperature within a first period of time, and the step of predicting a minimum ambient temperature within a preset period of time after the at least a period of time according to the minimum ambient temperature within the at least a period of time includes:

calculating the minimum ambient temperature within the preset period of time according to the minimum ambient temperature within the first period of time, a temperature constant, and a first ambient temperature predictive factor.

In one embodiment, the minimum ambient temperature within the at least a period of time includes a minimum ambient temperature within a first period of time and a minimum ambient temperature within a second period of time, the second period of time being after the first period of time, and the step of predicting a minimum ambient temperature within a preset period of time after the at least a period of time according to the minimum ambient temperature within the at least a period of time includes:

predicting the minimum ambient temperature within the preset period of time is the minimum ambient temperature within the first period of time, when determining that the minimum ambient temperature within the first period of time is less than or equal to the minimum ambient temperature within the second period of time.

In one embodiment, the minimum ambient temperature within the at least a period of time includes a minimum ambient temperature within a first period of time and a minimum ambient temperature within a second period of time, the second period of time being after the first period of time, and the step of predicting a minimum ambient temperature within a preset period of time after the at least a period of time according to the minimum ambient temperature within the at least a period of time includes:

calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

In one embodiment, the step of determining, according to the minimum ambient temperature within the preset period of time, a minimum state of charge value that able to meet power requirements for starting an engine of a vehicle under the minimum ambient temperature within the preset period of time includes:

substituting the minimum ambient temperature within the preset period of time in a discharge power Map of the power battery to obtain the minimum state of charge value.

Compared with the conventional art, the method for controlling a lower limit of a state of charge of a power battery of the present disclosure has the following advantages:

The present disclosure adopts a method for controlling a lower limit of a state of charge of a power battery, which includes: detecting a minimum ambient temperature for at least a period of time; predicting a minimum ambient temperature within a preset period of time after the at least a period of time according to the minimum ambient temperature within the at least a period of time; determining, according to the minimum ambient temperature within the preset period of time, a minimum state of charge value that able to meet power requirements for starting an engine of a vehicle under the minimum ambient temperature within the preset period of time; and adjusting a lower limit of the state of charge according to the minimum state of charge value. Since the minimum ambient temperature in the future preset period of time is predicted, therefore, the lower limit of the SOC of the battery is adjusted according to the minimum ambient temperature in the future preset period of time, so that the SOC value of the battery of the vehicle is not lower than the lower limit, so as to ensure that the SOC value of the battery can enable the vehicle to start normally in a low temperature environment.

Another aspect of the present disclosure is to provide a vehicle, including a device for controlling a lower limit of a state of charge of a power battery, so as to ensure that the SOC value of the battery can enable the vehicle to start normally in a low temperature environment.

To achieve the above aspect, the technical solution of the present disclosure is achieved as follows:

A device for controlling a lower limit of a state of charge of a power battery, and the device includes: a temperature sensor, configured for detecting a minimum ambient temperature for at least a period of time; a prediction unit, configured for predicting a minimum ambient temperature within a preset period of time after the at least a period of time according to the minimum ambient temperature within the at least a period of time; and a processor, configured for: determining, according to the minimum ambient temperature within the preset period of time, a minimum state of charge value that able to meet power requirements for starting an engine of a vehicle under the minimum ambient temperature within the preset period of time; and adjusting a lower limit of the state of charge according to the minimum state of charge value.

In one embodiment, the minimum ambient temperature within the at least a period of time only includes a minimum ambient temperature within a first period of time, and the prediction unit is configured for calculating the minimum ambient temperature within the preset period of time according to the minimum ambient temperature within the first period of time, a temperature constant, and a first ambient temperature predictive factor.

In one embodiment, the minimum ambient temperature within the at least a period of time includes a minimum ambient temperature within a first period of time and a minimum ambient temperature within a second period of time, the second period of time being after the first period of time, and the prediction unit is configured for predicting the minimum ambient temperature within the preset period of time is the minimum ambient temperature within the first period of time, when determining that the minimum ambient temperature within the first period of time is less than or equal to the minimum ambient temperature within the second period of time.

In one embodiment, the minimum ambient temperature within the at least a period of time includes a minimum ambient temperature within a first period of time and a minimum ambient temperature within a second period of time, the second period of time being after the first period of time, and the prediction unit is configured for calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

In one embodiment, the processor is configured for substituting the minimum ambient temperature within the preset period of time in a discharge power Map of the power battery to obtain the minimum state of charge value.

The device for controlling a lower limit of a state of charge of a power battery and the method for controlling a lower limit of a state of charge of a power battery have the same advantages relative to the conventional art, which is not repeated herein.

Another aspect of the present disclosure provides a vehicle, to ensure that the SOC value of the battery can enable the vehicle to start normally in a low temperature environment.

To achieve the above aspect, the technical solution of the present disclosure is achieved as following:

The vehicle and the device for controlling a lower limit of a state of charge of a power battery have the same advantages relative to the conventional art, which is not repeated herein.

Another aspect of the present disclosure provides a machine-readable storage medium, to ensure that the SOC value of the battery can enable the vehicle to start normally in a low temperature environment.

To achieve the above aspect, the technical solution of the present disclosure is achieved as following:

A machine-readable storage medium storing with instructions, and the instructions are configured to execute the method for controlling a lower limit of a state of charge of a power battery above-mentioned.

The machine-readable storage medium and the method for controlling a lower limit of a state of charge of a power battery have the same advantages relative to the conventional art, which is not repeated herein.

Other features and advantages of the present disclosure will be described in detail in the detailed description that follows.

### BRIEF DESCRIPTION

Some of the embodiments will be described in detail, with reference to the following figures, wherein like designations denote like members, wherein:

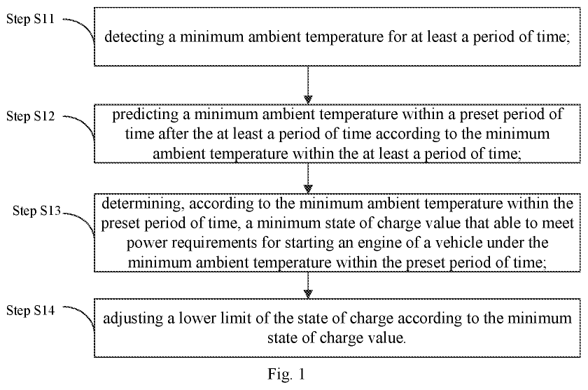

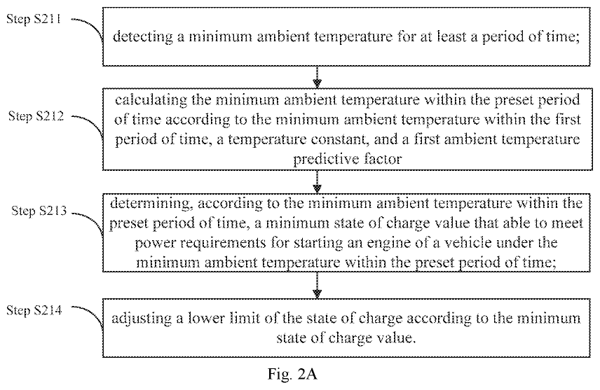

FIG. 1 is a flowchart of a method for controlling a lower limit of a state of charge of a power battery provided by an embodiment of the present disclosure;

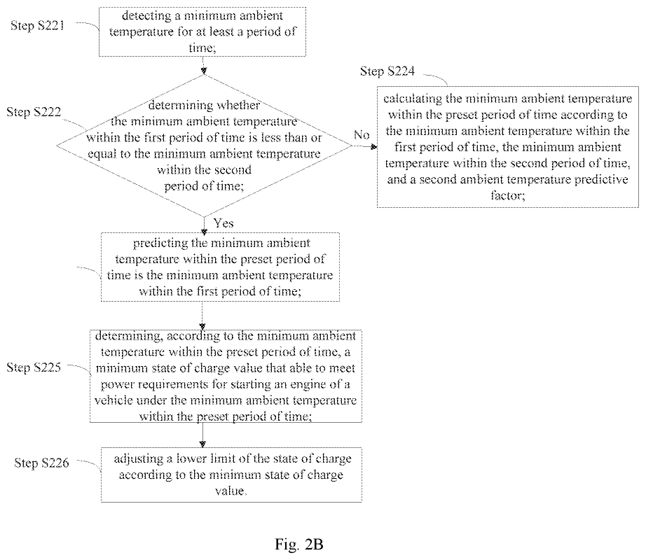

FIG. 2A is a flowchart of a method for controlling a lower limit of a state of charge of a power battery provided by another embodiment of the present disclosure;

FIG. 2B is a flowchart of a method for controlling a lower limit of a state of charge of a power battery provided by another embodiment of the present disclosure; and

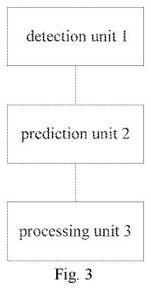

FIG. 3 is a structural block diagram of a device for controlling a lower limit of a state of charge of a power battery provided by an embodiment of the present disclosure.

In the drawings, the reference signs are listed:

1—temperature sensor; 2—prediction unit; and

3—processor.

### DETAILED DESCRIPTION

It should be noted that the embodiments of the present disclosure and the features of the embodiments can be combined with each other according to actual needs.

The present disclosure will be described in detail below with reference to the accompanying drawings and in conjunction with the embodiments.

FIG. 1 is a flowchart of a method for controlling a lower limit of a state of charge of a power battery provided by an embodiment of the present disclosure. As shown in FIG. 1, the method includes:

Step S11, detecting a minimum ambient temperature for at least a period of time;

Specifically, the ambient temperature can be detected by using a temperature sensor, and then the minimum ambient temperature can be calculated after the ambient temperature is stored. The at least a period of time can be, for example, a period of time, such as 5 days, 10 days, or 30 days; or two periods of time, such as two 5 days. If the at least a period of time represents two periods of time, then the respective minimum ambient temperatures of the two periods of time are obtained.

In one embodiment, since the present disclosure is directed to a vehicle, each functional device on the vehicle can also be used to perform the processing of detecting the minimum ambient temperature. For example, specifically:

The battery management system (BMS) wakes up from time to time (can be a plurality of times a day) and then wakes up the CAN network of the vehicle, and then waits for sleep; or T-Box wakes up from time to time (can be a plurality of times a day) and then wakes up the CAN network of the vehicle, and then waits for sleep. The air-conditioning controller is then woken up and sends the current ambient temperature to the hybrid vehicle unit (HCU), and then waits for sleep. After the head unit system (HUT) is woken up, the HUT sends the current date and time to the HCU, and then waits for sleep. After the HCU is woken up, the HCU receives the ambient temperature and updates the received ambient temperature to the ambient temperature record of the day, the minimum ambient temperature of the day is calculated based on the valid ambient temperature record of the day (not equal to the default value of 100, if the temperature detection of the air conditioner controller fails, the temperature is invalid), and then the minimum ambient temperature of the day is recorded, so that the minimum ambient temperature in any period of time can be obtained according to the daily minimum ambient temperature. If the daily ambient temperature records are invalid for a certain period of time (that is, the default value of 100), the minimum ambient temperature for that period is also invalid (that is, the default value of 100).

Step S12, predicting a minimum ambient temperature within a preset period of time after the at least a period of time according to the minimum ambient temperature within the at least a period of time;

Specifically, as shown in FIG. 2A, if at least a period of time is only a period of time, such as a first period of time, or at least a period of time is two periods of time, but the minimum ambient temperature for one of the two periods of time is invalid (that is, the default value of 100), then in this case, step S212 is performed instead of step S12, calculating the minimum ambient temperature within the preset period of time according to the minimum ambient temperature within the first period of time, a temperature constant, and a first ambient temperature predictive factor. The specific calculation formula is:

T0=T1+C×q1

The T0 represents the minimum ambient temperature in the preset period of time; the T1 represents the minimum ambient temperature in the first period of time; the C represents the temperature constant; and the q1 represents the first ambient temperature predictive factor. The temperature constant is, for example, −5° C., and this value can be calibrated according to actual needs. The first ambient temperature predictive factor can be obtained by substituting the minimum ambient temperature T1 in the first period of time and querying the “correspondence table between the ambient temperature predictive factor and the minimum ambient temperature”. The first ambient temperature predictive factor q1 is ranged from 0 to 2. The “correspondence table between the ambient temperature predictive factor and the minimum ambient temperature” can be obtained by pre-calibration. For example, when the minimum ambient temperature for the next 10 days (that is, the preset period of time above) is needed to be predicted based on the minimum ambient temperature of the first 10 days, after the temperature constant C is set, then the minimum ambient temperature for the first 10 days is detected, and the minimum ambient temperature for the next 10 days is detected, and then substituting the minimum ambient temperatures in the above formula T0=T1+C×q1 to obtain the first ambient temperature predictive factor q1, the above processing then being performed a plurality of times, the first ambient temperature predictive factor q1 corresponding to the minimum ambient temperature in the first 10 days can be obtained through a large amount of actual data. This calibration method is relatively common and will not be repeated here.

As shown in FIG. 2B, if the at least a period of time is two periods of time, namely a first period of time and a second period of time (the second period of time is after the first period of time), and when the minimum ambient temperatures of the two periods of time are valid, then perform the following steps S222-S224 instead of step S12:

Step S222, determining whether the minimum ambient temperature within the first period of time is less than or equal to the minimum ambient temperature within the second period of time;

Step S223, predicting the minimum ambient temperature within the preset period of time is the minimum ambient temperature within the first period of time, when the minimum ambient temperature within the first period of time is less than or equal to the minimum ambient temperature within the second period of time.

Step S224, calculating the minimum ambient temperature within the preset period of time according to the minimum ambient temperature within the first period of time, the minimum ambient temperature within the second period of time, and a second ambient temperature predictive factor, when the minimum ambient temperature within the first period of time is larger than the minimum ambient temperature within the second period of time.

In the step S224, the specific calculation formula is:

T0=T2+(T2−T1)×q2

The T0 represents the minimum ambient temperature in the preset period of time; the T1 represents the minimum ambient temperature in the first period of time; the T2 represents the minimum ambient temperature in the second period of time; and the q2 represents the second ambient temperature predictive factor. The second ambient temperature predictive factor q2 can be obtained by substituting the difference between the minimum ambient temperature T1 in the first period of time and the minimum ambient temperature in the second period of time and querying the “correspondence table between the ambient temperature predictive factor and the minimum ambient temperature”. The second ambient temperature predictive factor q2 is ranged from 0 to 2.

Step S13, determining, according to the minimum ambient temperature within the preset period of time, a minimum state of charge value that able to meet power requirements for starting an engine of a vehicle under the minimum ambient temperature within the preset period of time;

Specifically, substituting the minimum ambient temperature within the preset period of time in a discharge power Map of the power battery to obtain the minimum SOC value, the discharge power Map of the power battery is known, and the Map varies according to the vehicle or the power battery.

Step S14, adjusting a lower limit of the state of charge according to the minimum state of charge value.

Specifically, a reserve amount is added to the minimum SOC value as the lower limit of the predicted SOC to ensure a low temperature cold start of the engine. In another embodiment, the larger between the lower limit of the predicted SOC ensuring a low temperature cold start of the engine and the lower limit of the usage of the battery pack SOC defined by the battery supplier is served as the final lower limit of SOC value. If it is predicted that the temperature will decrease in the next 10 days, and the SOC value needs to be above 25% to start the vehicle normally, then adjusting the lower limit of the SOC from the fixed 15% to 25%, so that the SOC value cannot be lower than 25%, for example, the vehicle is stopped to used when the SOC value is lower than 25%, or keep charging above 25% when the SOC value is lower than 25%, which can solve the problem that after the power battery is powered off after the vehicle is stopped, the engine cannot be started and the vehicle cannot be used since the temperature of the power battery pack will decrease due to the decrease of the ambient temperature in the next 10 days, so that the discharge power of the battery does not meet the starting power requirement of the engine.

FIG. 3 is a structural block diagram of a device for controlling a lower limit of a state of charge of a power battery provided by an embodiment of the present disclosure. As shown in FIG. 3, the device includes: a temperature sensor 1, a prediction unit 2 and a processor 3. The temperature sensor 1 is configured for detecting a minimum ambient temperature for at least a period of time; the prediction unit 2 is configured for predicting a minimum ambient temperature within a preset period of time after the at least a period of time according to the minimum ambient temperature within the at least a period of time; and the processor 3 is configured for determining, according to the minimum ambient temperature within the preset period of time, a minimum state of charge value that able to meet power requirements for starting an engine of a vehicle under the minimum ambient temperature within the preset period of time; and adjusting a lower limit of the state of charge according to the minimum state of charge value.

In one embodiment, the minimum ambient temperature within the at least a period of time only includes a minimum ambient temperature within a first period of time, and the prediction unit 2 is configured for calculating the minimum ambient temperature within the preset period of time according to the minimum ambient temperature within the first period of time, a temperature constant, and a first ambient temperature predictive factor.

In one embodiment, the minimum ambient temperature within the at least a period of time includes a minimum ambient temperature within a first period of time and a minimum ambient temperature within a second period of time, the second period of time being after the first period of time, and the prediction unit 2 is configured for predicting the minimum ambient temperature within the preset period of time is the minimum ambient temperature within the first period of time, when determining that the minimum ambient temperature within the first period of time is less than or equal to the minimum ambient temperature within the second period of time.

In one embodiment, the minimum ambient temperature within the at least a period of time includes a minimum ambient temperature within a first period of time and a minimum ambient temperature within a second period of time, the second period of time being after the first period of time, and the prediction unit 2 is configured for calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

In one embodiment, the processor 3 is configured for substituting the minimum ambient temperature within the preset period of time in a discharge power Map of the power battery to obtain the minimum state of charge value.

The embodiments of the device for controlling a lower limit of a state of charge of a power battery described above are similar to the embodiments of the method for controlling a lower limit of a state of charge of a power battery described above, which will not be repeated here.

The present disclosure further provides a vehicle including the above-mentioned device for controlling a lower limit of a state of charge of a power battery.

The present disclosure further provides a machine-readable storage medium storing with instructions, and the instructions are configured to execute the method for controlling a lower limit of a state of charge of a power battery through a machine.

The embodiments of the vehicle and the machine-readable storage medium described above are similar to the embodiments of the method for controlling a lower limit of a state of charge of a power battery described above, which will not be repeated here.

Although the invention has been illustrated and described in greater detail with reference to the preferred exemplary embodiment, the invention is not limited to the examples disclosed, and further variations can be inferred by a person skilled in the art, without departing from the scope of protection of the invention.

For the sake of clarity, it is to be understood that the use of “a” or “an” throughout this application does not exclude a plurality, and “comprising” does not exclude other steps or elements.

What is claimed is:

1. A method for controlling a lower limit of a state of charge of a power battery, the method comprising:
detecting, through a temperature sensor, a minimum ambient temperature for at least a period of time;
predicting a minimum ambient temperature within a preset period of time after the at least a period of time according to the minimum ambient temperature within the at least a period of time;
determining, according to the minimum ambient temperature within the preset period of time, a minimum state of charge value that is able to meet power requirements for starting an engine of a vehicle under the minimum ambient temperature within the preset period of time; and
adjusting the lower limit of the state of charge according to the minimum state of charge value.

2. The method according to claim 1, wherein the minimum ambient temperature within the at least a period of time only comprises a minimum ambient temperature within a first period of time, and predicting the minimum ambient temperature within the preset period of time after the at least a period of time according to the minimum ambient temperature within the at least a period of time comprises:
calculating the minimum ambient temperature within the preset period of time according to the minimum ambient temperature within the first period of time, a temperature constant, and a first ambient temperature predictive factor.

3. The method according to claim 1, wherein the minimum ambient temperature within the at least a period of time comprises a minimum ambient temperature within a first period of time and a minimum ambient temperature within a second period of time, the second period of time being after the first period of time, and predicting the minimum ambient temperature within the preset period of time after the at least a period of time according to the minimum ambient temperature within the at least a period of time comprises:
predicting the minimum ambient temperature within the preset period of time is the minimum ambient temperature within the first period of time, when determining that the minimum ambient temperature within the first period of time is less than or equal to the minimum ambient temperature within the second period of time.

4. The method according to claim 1, wherein the minimum ambient temperature within the at least a period of time comprises a minimum ambient temperature within a first period of time and a minimum ambient temperature within a second period of time, the second period of time being after the first period of time, and predicting a minimum ambient temperature within a preset period of time after the at least a period of time according to the minimum ambient temperature within the at least a period of time comprises:
calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

5. The method according to claim 1, wherein the determining, according to the minimum ambient temperature within the preset period of time, the minimum state of charge value that is able to meet power requirements for starting the engine of the vehicle under the minimum ambient temperature within the preset period of time comprises:
substituting the minimum ambient temperature within the preset period of time in a discharge power Map of the power battery to obtain the minimum state of charge value.

6. A vehicle comprising:
a device for controlling a lower limit of a state of charge of a power battery, the device comprises:
q temperature sensor, configured for detecting a minimum ambient temperature for at least a period of time;
a prediction unit, configured for predicting a minimum ambient temperature within a preset period of time after the at least a period of time according to the minimum ambient temperature within the at least a period of time; and
a processor, configured for:
determining, according to the minimum ambient temperature within the preset period of time, a minimum state of charge value that is able to meet power requirements for starting an engine of a vehicle under the minimum ambient temperature within the preset period of time; and
adjusting the lower limit of the state of charge according to the minimum state of charge value.

7. The vehicle according to claim 6, wherein the minimum ambient temperature within the at least a period of time only comprises a minimum ambient temperature within a first period of time, and the prediction unit is configured for:
calculating the minimum ambient temperature within the preset period of time according to the minimum ambient temperature within the first period of time, a temperature constant, and a first ambient temperature predictive factor.

8. The vehicle according to claim 6, wherein the minimum ambient temperature within the at least a period of time comprises a minimum ambient temperature within a first period of time and a minimum ambient temperature within a second period of time, the second period of time being after the first period of time, and the prediction unit is configured for:
predicting the minimum ambient temperature within the preset period of time is the minimum ambient temperature within the first period of time, when determining that the minimum ambient temperature within the first period of time is less than or equal to the minimum ambient temperature within the second period of time.

9. The vehicle according to claim 6, wherein the minimum ambient temperature within the at least a period of time comprises a minimum ambient temperature within a first period of time and a minimum ambient temperature within a second period of time, the second period of time being after the first period of time, and the prediction unit is configured for:
calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

10. The vehicle according to claim 6, wherein the processor is configured for:
substituting the minimum ambient temperature within the preset period of time in a discharge power Map of the power battery to obtain the minimum state of charge value.

11. A machine-readable storage medium storing with instructions, wherein the instructions are configured to execute a method for controlling a lower limit of a state of charge of a power battery, and further configured to execute:
detecting, through a temperature sensor, a minimum ambient temperature for at least a period of time;
predicting a minimum ambient temperature within a preset period of time after the at least a period of time according to the minimum ambient temperature within the at least a period of time;
determining, according to the minimum ambient temperature within the preset period of time, a minimum state of charge value that is able to meet power requirements for starting an engine of a vehicle under the minimum ambient temperature within the preset period of time; and
adjusting the lower limit of the state of charge according to the minimum state of charge value.

12. The machine-readable storage medium according to claim 11, wherein the minimum ambient temperature within the at least a period of time only comprises a minimum ambient temperature within a first period of time, and predicting the minimum ambient temperature within the preset period of time after the at least a period of time according to the minimum ambient temperature within the at least a period of time comprises:
calculating the minimum ambient temperature within the preset period of time according to the minimum ambient temperature within the first period of time, a temperature constant, and a first ambient temperature predictive factor.

13. The machine-readable storage medium according to claim 11, wherein the minimum ambient temperature within the at least a period of time comprises a minimum ambient temperature within a first period of time and a minimum ambient temperature within a second period of time, the second period of time being after the first period of time, and predicting the minimum ambient temperature within the preset period of time after the at least a period of time according to the minimum ambient temperature within the at least a period of time comprises:
predicting the minimum ambient temperature within the preset period of time is the minimum ambient temperature within the first period of time, when determining that the minimum ambient temperature within the first period of time is less than or equal to the minimum ambient temperature within the second period of time.

14. The machine-readable storage medium according to claim 11, wherein the minimum ambient temperature within the at least a period of time comprises a minimum ambient temperature within a first period of time and a minimum ambient temperature within a second period of time, the second period of time being after the first period of time, and the predicting the minimum ambient temperature within the preset period of time after the at least a period of time according to the minimum ambient temperature within the at least a period of time comprises:
calculating the minimum ambient temperature within the preset period of time according to the minimum ambient temperature within the first period of time, the minimum ambient temperature within the second period of time, and a second ambient temperature predictive factor, when determining that the minimum ambient temperature within the first period of time is larger than the minimum ambient temperature within the second period of time.

15. The machine-readable storage medium according to claim 11, wherein the determining, according to the minimum ambient temperature within the preset period of time, the minimum state of charge value that is able to meet power requirements for starting the engine of the vehicle under the minimum ambient temperature within the preset period of time comprises:
substituting the minimum ambient temperature within the preset period of time in a discharge power Map of the power battery to obtain the minimum state of charge value.
